(19) United States
(12) Patent Application Publication
(10) Pub. No.: US 2023/0008882 A1
(43) Pub. Date: Jan. 12, 2023

(54) Temporary Deactivation Of Smoke Detector

(71) Applicant: Robert Collier Lancaster, Frankfort, KY (US)

(72) Inventor: Robert Collier Lancaster, Frankfort, KY (US)

(21) Appl. No.: 17/372,478

(22) Filed: Jul. 11, 2021

(51) Int. Cl. G08B 29/18; G08B 17/10; H05K 5/02; H05K 5/03; H05K 5/06; H05K 5/00

(52) U.S. Cl. CPC G08B 29/18; G08B 17/10; H05K 5/023; H05K 5/03; H05K 5/061; H05K 5/069; H05K 5/0086

(57) ABSTRACT

A cover to temporarily deactivate a smoke detector. The cover is placed over a smoke detector to temporarily prevent smoke detection and removed when the smoke producing activity has been completed.

### CROSS-REFERENCE TO RELATED APPLICATIONS

Not Applicable

### BACKGROUND OF THE INVENTION

This invention relates to smoke detectors and, more particularly, the invention relates to deactivating smoke detection of an alarm.

There can be many reasons one may wish to temporarily deactivate a smoke alarm but there are two common scenarios.

Food preparation sometimes includes cooking meat or fish at a high temperature for searing or browning. This can often overwhelm a range hood and lead to enough smoke entering the room to set off a sensitive smoke alarm.

Another common occurrence is a smoke alarm triggering while using a torch, welding or other activities that produce smoke in a workshop.

A startling loud alarm in the middle of an activity involving fire or high heat can lead to severe injuries or cause a fire to start as a person tries to quiet the blaring alarm. Additionally, in frustration, many people simply remove the alarm permanently. This creates an even greater risk of injury or even death. Therefore, a need exists to be able to temporarily deactivate a smoke alarm during a particular activity.

### BRIEF SUMMARY OF THE INVENTION

The present invention comprises a novel smoke detector cover consisting of a cap, placement handle and sealing gasket. The cover is placed over a smoke detector to temporarily prevent smoke detection and is removed when the smoke producing activity has ceased.

### BRIEF DESCRIPTION OF THE DRAWINGS

FIG. 1 depicts the front side of one example of a cover according to various embodiments of the present invention.

FIG. 2 depicts the right side of a cover according to various embodiments of the present invention.

FIG. 3 depicts the back side of a cover with sealing gasket according to various embodiments of the present invention.

FIG. 4 depicts the back side of a cover with sealing gasket removed and depicting alarm griping pads according to various embodiments of the present invention.

FIG. 5 depicts the exploded view of the cover according to various embodiments of the present invention.

FIG. 6 depicts a cross section of an assembled cover according to various embodiments of the present invention.

FIG. 7 illustrates placing a cover over a smoke detector according to various embodiments of the present invention.

FIG. 8 depicts a cover fully installed on the smoke detector 700 referenced in FIG. 7 according to various embodiments of the present invention.

### DETAILED DESCRIPTION OF THE INVENTION

The terminology used herein is for the purpose of describing particular embodiments only and is not intended to be limiting of the invention. As used herein, the term “and/or” includes any and all combinations of one or more of the associated listed items. As used herein, the singular forms “a,” “an,” and “the” are intended to include the plural forms as well as the singular forms, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof.

Unless otherwise defined, all terms used herein have the same meaning as commonly understood by one having ordinary skill in the art to which this invention belongs. It will be further understood that terms, such as those defined in commonly used dictionaries, should be interpreted as having a meaning that is consistent with their meaning in the context of the relevant art and the present disclosure and will not be interpreted in an idealized or overly formal sense unless expressly so defined herein.

The present disclosure is to be considered as an exemplification of the invention, and is not intended to limit the invention to the specific embodiments illustrated by the figures or description below.

The present invention will now be described by referencing the appended figures representing preferred embodiments.

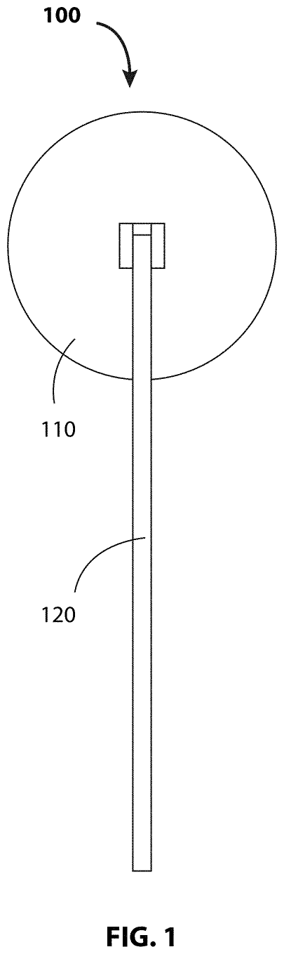

FIG. 1 depicts the front side of the cover 100 in one embodiment of the invention including the cap 110 and placement handle 120.

The cap 110 is sized and shaped to completely enclose a particular smoke alarm. The cap 110 may be formed of various suitable materials. In one implementation, the cap 110 is formed of smoke-impervious material typically urethane resin or thermoplastic material.

The placement handle 120 is of particular length to allow cover 100 placement over smoke alarm typically mounted on the wall close to the ceiling. The placement handle 120 may be formed of various suitable materials. In one implementation, the placement handle 120 is formed of aluminum rod.

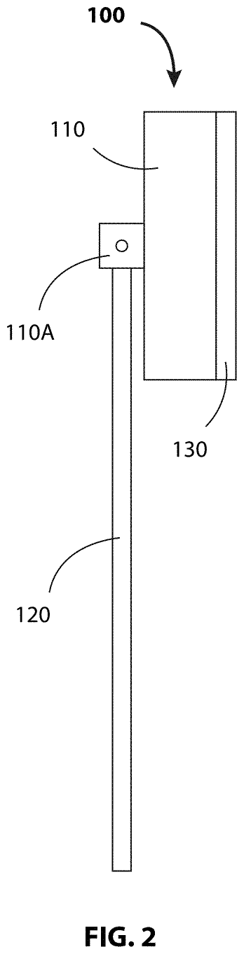

FIG. 2 depicts the right side view of the cover 100 in one embodiment of the invention including the cap 110, placement handle 120, and sealing gasket 130.

In one implementation, the cap 110 includes a handle attachment feature 110A to attach the placement handle 120 to the cap 110. Attachment is typically achieved with a pin or screw of suitable material.

The sealing gasket 130 is formed of flexible material typically silicone or rubber material which prevents smoke from entering the cap 110 by sealing against the wall to which the smoke alarm is attached.

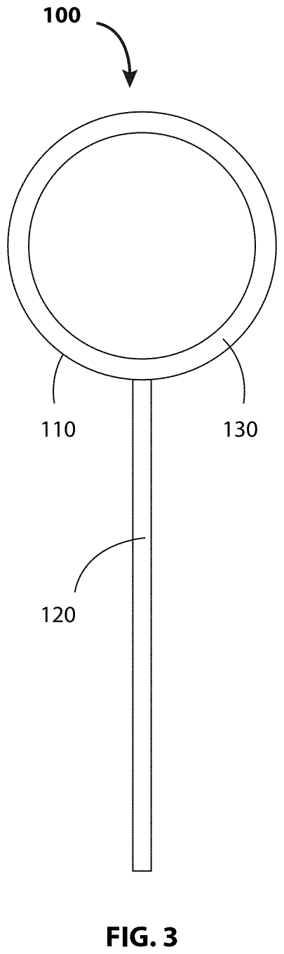

FIG. 3 depicts the back side of the cover 100 in one embodiment of the invention including the cap 110, placement handle 120 and sealing gasket 130.

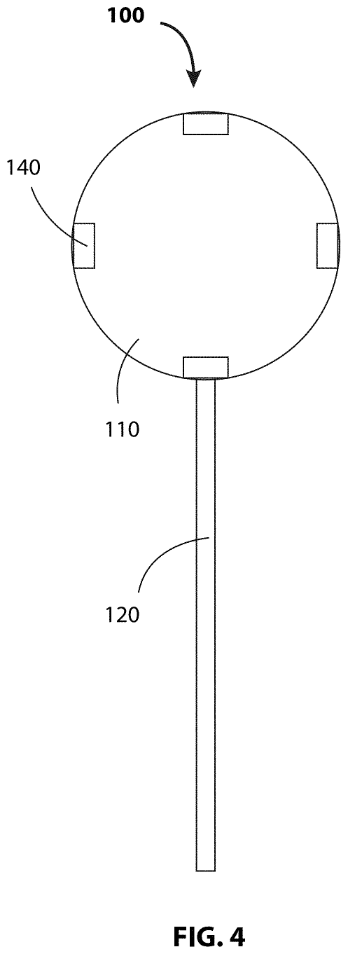

FIG. 4 depicts the back side of the cover 100 in one embodiment of the invention, with the sealing gasket 130 removed, including the cap 110, placement handle 120 and gripping pads 140.

The gripping pads 140 are formed of flexible material typically foam rubber material which fits over the smoke alarm to hold the cover in place. Pluralities of gripping pads are used suitable to gripping a particular smoke alarm.

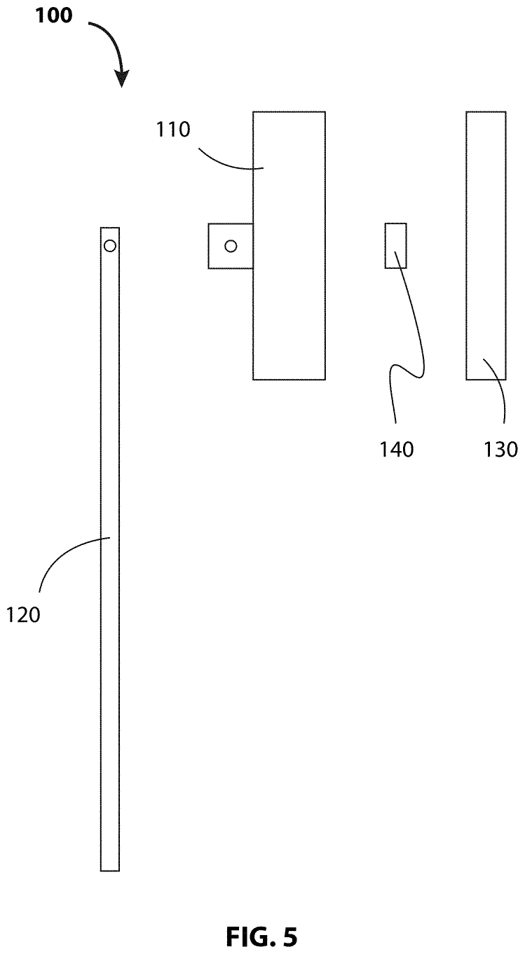

FIG. 5 depicts the exploded view of the parts of the cover 100 in one embodiment of the invention including the cap 110, placement handle 120, gripping pad 140 and sealing gasket 130.

Placement handle 120 includes a hole for attaching to the cap 110 as referenced in FIG. 2. The placement handle 120 hole also allows the cap 110 to pivot during placement over smoke alarm.

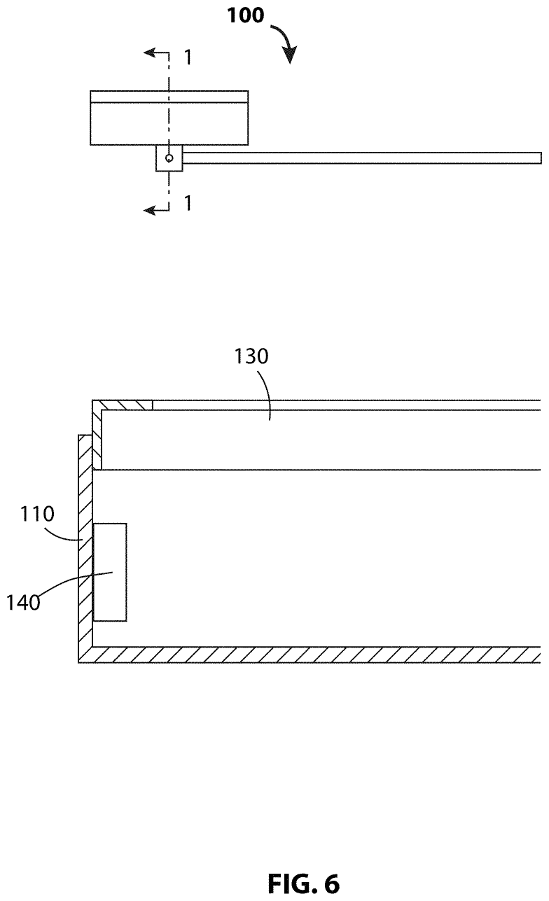

FIG. 6 depicts a cross section of an assembled cover 100 according to one embodiment of the invention.

The sealing gasket 130 is bonded with adhesive and/or mechanically connected to the inside of the cap 110 to sufficiently prevent smoke from entering the cap 110.

The gripping pad 140 is bonded to the inside of the cap 110 typically with a suitable adhesive.

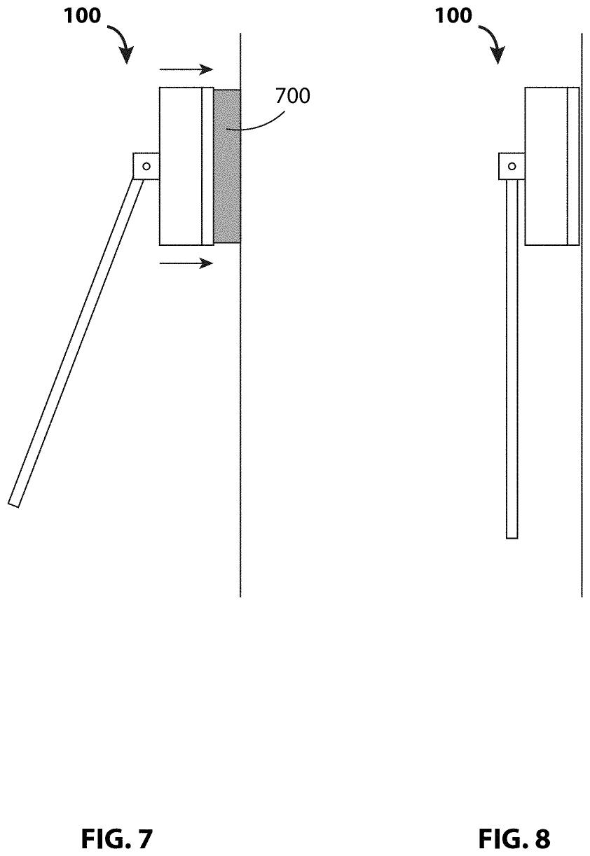

FIG. 7 depicts placing the cover 100 over a smoke alarm 700.

FIG. 8 depicts the cover 100 temporarily deactivating a smoke alarm 700 referenced in FIG. 7.

1. A device for temporarily disabling a smoke alarm comprising: a smoke alarm cap; a handle for placement of the cover over the smoke alarm; and a flexible gasket attached to the cap to seal the cover against the wall.

2. The device of claim 1, wherein: the cover further comprises a plurality of gripping pads to temporarily secure the cover over the smoke alarm.
